(19) United States
(12) Patent Application Publication
(10) Pub. No.: US 2023/0253398 A1
(43) Pub. Date: Aug. 10, 2023

(54) SEMICONDUCTOR DEVICE

(71) Applicant: RENESAS ELECTRONICS CORPORATION, Tokyo (JP)

(72) Inventor: Yusuke OJIMA, Tokyo (JP)

(21) Appl. No.: 17/668,886

(22) Filed: Feb. 10, 2022

(51) Int. Cl. H01L 27/02

(52) U.S. Cl. CPC H01L 27/0274; H02J 7/0029

(57) ABSTRACT

A semiconductor device includes a first power semiconductor device, a first Nch MOSFET whose drain is coupled to a gate of the first power semiconductor device, a first gate resistor coupled to a source of the first Nch MOSFET and a first diode coupled between the source and drain of the first Nch MOSFET.

### BACKGROUND

The present invention relates to a semiconductor device, particularly a semiconductor device having a power semiconductor device.

For Battery management system (BMS) for controlling the charging and discharging of a built-in battery such as a power tool and a mobile device, and control system for a motor, a power semiconductor device (power MOSFET, IGBT, etc.) is utilized. The power semiconductor device is required to have low loss (low on-resistance) and gate driving by low voltage from the viewpoint of performance and power saving. Furthermore, for these systems, it is also required to mount a protection system so that the power semiconductor device and a control IC of the power semiconductor device are not destroyed when an anomaly, such as an overcurrent or a short circuit, is occurred.

The BMS shuts off the power supply from the battery by turning off the power semiconductor device in the event of an anomaly. However, when the power semiconductor device is turned off steeply, the wiring parasitic inductance inside and outside the battery cell, surge voltage is generated. Since the battery for such as the power tool has a high current supply capability and a large parasitic inductance, the surge voltage also increases. Large surge voltages can destroy the battery and the control IC.

Provided with a gate resistor to the gate of the power semiconductor device, it is possible to suppress the surge voltage by suppressing the steep turn-off. Patent Document 1 discloses dividing a gate electrode into a plurality of gate electrodes and connecting different gate resistors each of which has a different resistance value to the respective gate electrodes. Thus, without increasing the switching delay, it possible to suppress the surge voltage at turn-off.

### PRIOR ART DOCUMENT

### Patent Document

[Patent Document 1] Japanese Unexamined Publication Laid-Open No. 2018-107693

### SUMMARY

According to the technique described in Patent Document 1, it is possible to suppress the surge voltage at the time of turn-off. However, it is difficult to make the slew rate at the turn-off of the power semiconductor device variable. When the slew rate becomes fixed, the gate resistance must be determined after considering various applications at the design stage. In some cases, a design change is necessary after shipment.

Other objects and novel features will become apparent from the description of the specification and drawings.

A semiconductor device according to an embodiment includes a first power semiconductor device, a first Nch MOSFET whose drain is coupled to a gate of the first power semiconductor device, first gate resistor coupled to a source of the first Nch MOSFET and a first diode coupled between the source and drain of the first Nch MOSFET.

In the semiconductor device according to an embodiment, it is possible to make the slew rate at the time of turn-off of the power semiconductor device variable, and it also possible to suppress the surge voltage.

BRIEF DESCRIPTION OF THE DRAWINGS

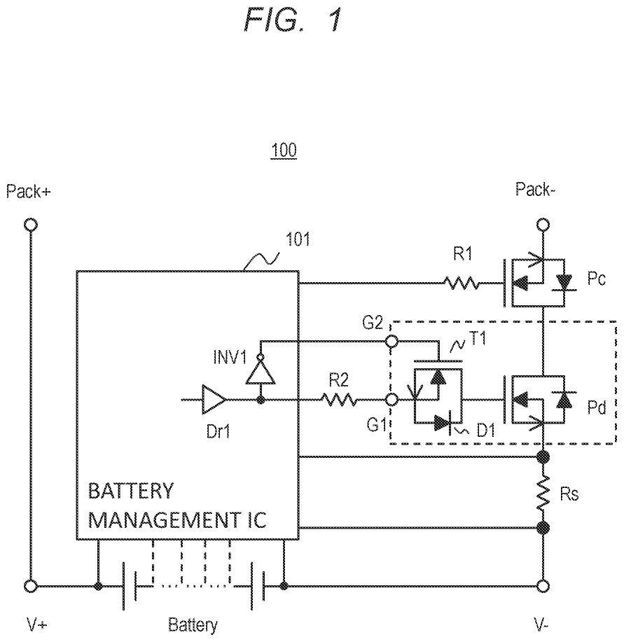

FIG. 1 is a block diagram of a semiconductor device according to a first embodiment.

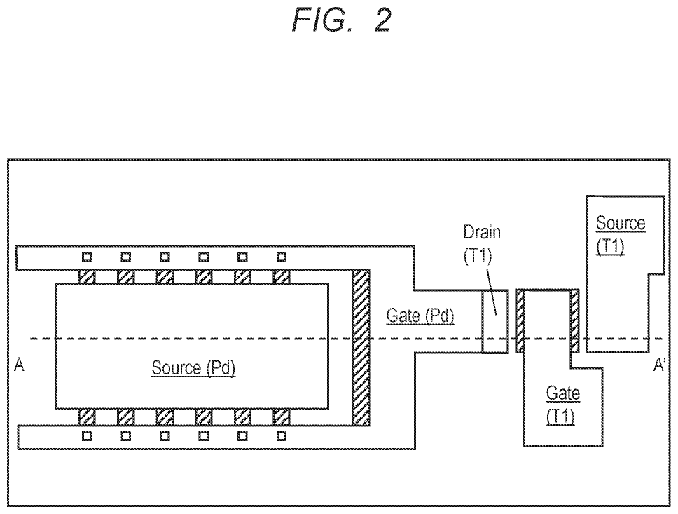

FIG. 2 is a plan view of the semiconductor device according to the first embodiment.

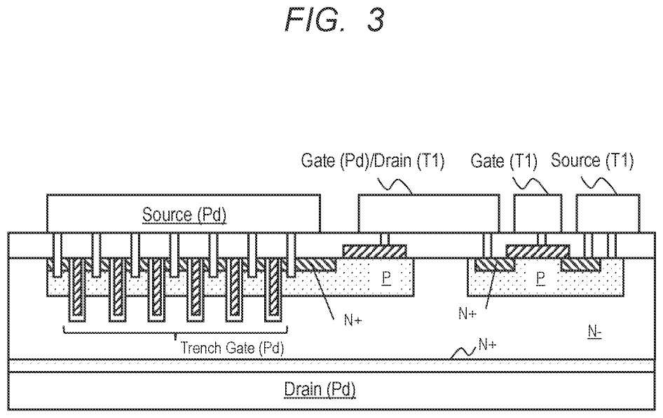

FIG. 3 is a cross-sectional view of the semiconductor device according to the first embodiment.

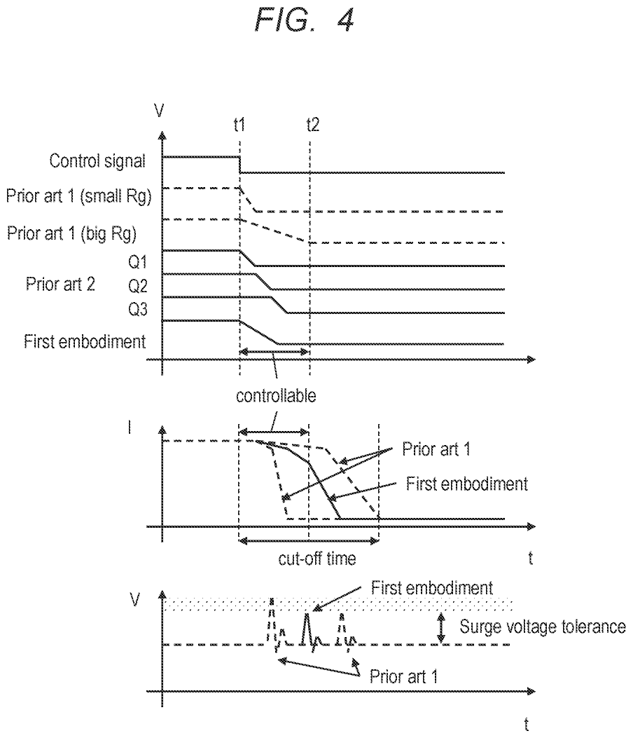

FIG. 4 is a timing chart for explaining the operation of the semiconductor device according to the first embodiment.

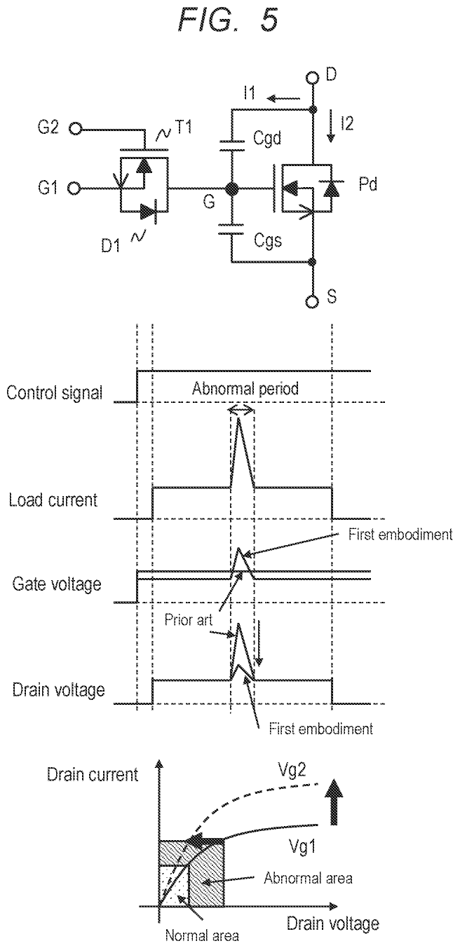

FIG. 5 is a timing chart for explaining the operation of the semiconductor device according to the first embodiment.

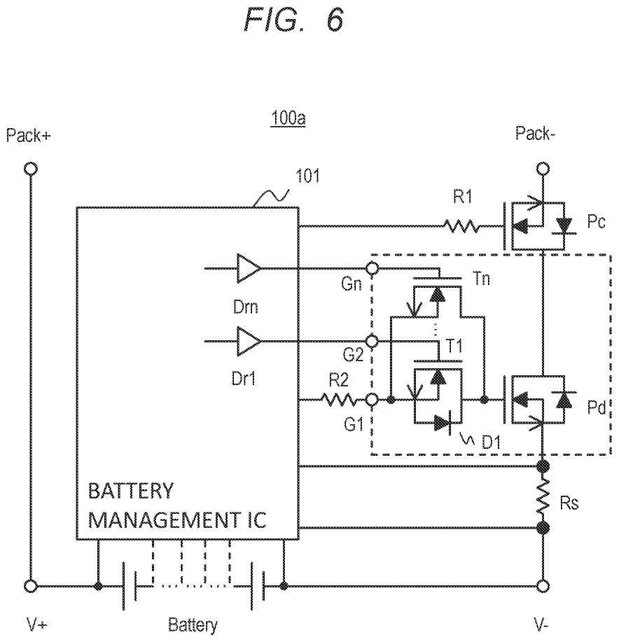

FIG. 6 is a block diagram of a semiconductor device according to a second embodiment.

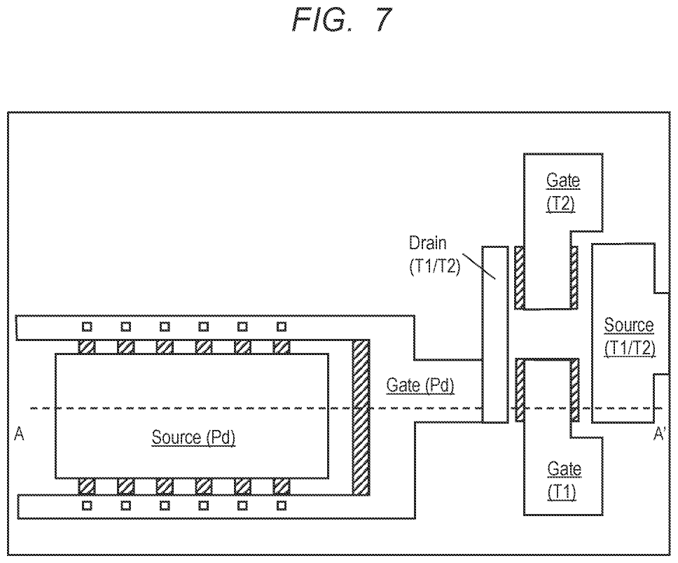

FIG. 7 is a plan view of the semiconductor device according to the second embodiment.

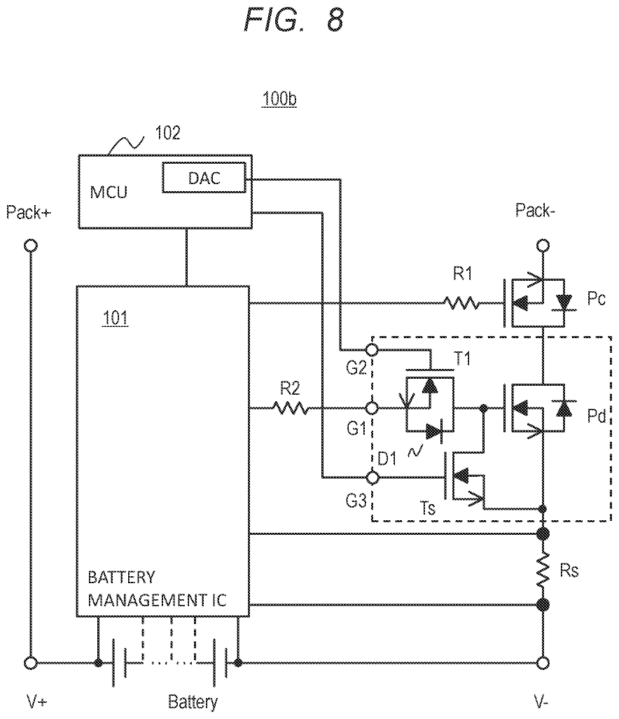

FIG. 8 is a block diagram of the semiconductor device according to a third embodiment.

### DETAILED DESCRIPTION

Hereinafter, a semiconductor device according to an embodiment will be described in detail by referring to the drawings. In the specification and the drawings, the same or corresponding form elements are denoted by the same reference numerals, and a repetitive description thereof is omitted. In the drawings, for convenience of description, the configuration may be omitted or simplified. Also, at least some of the embodiments may be arbitrarily combined with each other.

### First Embodiment

FIG. 1 is a block diagram showing a configuration of a semiconductor device 100 according to the first embodiment. Here, the EMS will be described as an example. As shown in FIG. 1, the semiconductor device 100 includes the battery composed of a plurality of cells, the battery management IC (EMIC) 101, the power semiconductor device Pc for charging protection (hereinafter, Pc), the power semiconductor device Pd for so discharging protection (hereinafter, Pd), the shunt resistor Rs. Pc and Pd are controlled by EMIC 101. That is, the gate signals outputted from EMIC 101 are supplied to the gates of Pc and Pd. R1 is a gate resistance of Pc, R2 is a gate resistance of Pd. In the first embodiment, a control Nch MOSFET T1 is further connected between the gate resistors R2 and Pd. D1 is a body diode of the control MOSFET T1. The gate of the control MOSFET T1 is supplied with an inverted signal of the gate signal outputted from BMIC 101. Incidentally, for simplicity in FIG. 1, the control MOSFET T1 is connected to only Pd, Pc may have the same configuration.

FIG. 2 is a plan view of a chip in the case where Pd and T1 are configured by one chip. FIG. 3 is a cross-sectional view taken along A-A′ of FIG. 2. Here, Pd is composed of a trench gate type power semiconductor device. As is apparent from FIGS. 2 and 3, T1 is formed in a region outside the region where Pd is formed.

Next, a basic operation of the semiconductor device 100 will be described. When charging the battery, a power is supplied from a power source connected between Pack+, Pack− terminals to charge the battery. In this case, EMIC 101 turns on Pc. BMIC 101 monitors the voltages of the cells constituting the battery. SMIC 101 turns off Pc when it detects an overcharge of the battery.

When discharging the battery, i.e. supplying power from the battery to the loads connected between Pack+ and Pack− terminals, SMIC 101 turns on Pd. When SMIC 101 detects an over discharge of the battery, it turns off Pd.

Next, the operation of the semiconductors device 100 will be described. FIG. 4 is a timing chart for explaining the operation of the semiconductor device 100 when Pd is turned off. As described above, in order to turn on Pd when discharging the battery, High control signals are supplied from BMIC 101 to the gate terminal G1. Low control signal is supplied to the gate terminal G2. At this time, the control MOSFET T1 is turned off, but the gate of Pd is turned on because the voltage rises through the body diode D1 (to time t1). When Pd is turned off, BMIC 101 sets the gate terminal G1 to Low and the gate terminal G2 to High time t1. The gate voltage of Pd drops to Low via the control MOSFET T1. At this time, by controlling the voltage supplied to the gate terminal G2, BMIC 101 can control the slew rate of the drop of the gate voltage of Pd. Because the on-resistance of the control MOSFET T1 depends on the gate voltage of the gate terminal G2. Therefore, as shown in FIG. 4, in the first embodiment, the slew rate (times t1 to t2) when Pd is turned off can be made variable. Further, by controlling the control signal applying timing to the gate terminal G2, it is possible to also control the turn-off start time. Voltage and timing of the control signal supplied to the gate terminal G2, for example, can be realized by varying the power supply voltage and delay value of the inverter INV1.

FIG. 4 also shows a timing chart of the prior art for reference. Prior art 1 is EMS in which the control MOSFET T1 in FIG. 1 is not arranged. In “Prior art 1” the gate resistor is fixed at the designed value because only R1 and R2 are used for the gate resistor. The slew rate of turn-off becomes steep when resistor values of R1 and R2 are decreased, and the slew rate of turn-off becomes gentle when resistor values of R1 and R2 are increased. In prior art 1, It is difficult to make the slew rate variable as in the first embodiment.

“Prior art 2” is the Patent Document 1. In the Patent Document 1, the gate electrode is divided into a plurality of gate electrodes, and gate resistors each of which has a different resistance value (e.g., Q1 to Q3) are connected to the divided gate electrodes, respectively. Thus, by turning off stepwise, the peak voltage of the surge is suppressed. However, as with Prior art 1, it is difficult to make the slew rate variable,

Further, the operation of the semiconductor device 100 will be described. FIG. 5 shows an enlarged view of the control MOSFET T1 and Pd. Note that Cgd is a parasitic capacitance between the gate and the drain of Pd. Cgs is the gate-source parasitic capacitance of Pd. When Pd is on, the current flowing through the parasitic capacitance Cgd is denoted by I1, and the current flowing through Pd is denoted by I2. From the viewpoint of Pd, the charge of the parasitic capacitance Cgd cannot flow out because the gate G is a high impedance by the body diode D1. The gate G is ideally can be raised to a voltage V expressed by the following equation.

V=(I1*t)/Cgd (t: current I1 application time)

If an anomaly occurs and overcurrent flows while Pd is on, the load current I2 greatly increases. Since the current I1 also increases, the voltage of the gate G also increases. When the voltage of the gate G rises, the on-resistance of Pd is lowered and the voltage of the drain is lowered.

That is, according to the first embodiment, even if an overcurrent flows, a sudden rise in the drain voltage of Pd can be suppressed, and a destruction of Pd can be avoided.

As described above, in the semiconductor device 100 according to the first embodiment, by the control MOSFET T1 and the body diode D1, the slew rate at the time of turn-off of the Pd can be is variable, further, it is possible to avoid breakage of the Pd when abnormal.

In FIG. 1, the control signal supplied to the gate terminal G2 is an inverted signal of the control signal supplied to the gate terminal G1, but it is not limited thereto. The control signal of the gate terminal G1 and the control signal of the gate terminal G2 may be generated independently. Thus, an arbitrary voltage can be applied to the gate terminal G2 at any timing.

### Second Embodiment

FIG. 6 is a block diagram showing a configuration of a semiconductor device 100a according to the second embodiment. The difference from the first embodiment is that the control MOSFET is composed of a plurality of T1 to Tn connected in parallel. Each of the control MOSFETs T1 to Tn may have the same or different on-resistance.

FIG. 7 is a surface view of the chip in the case where Pd, T1, and T2 are configured by one chip. Cross-sectional view of A-A′ line of FIG. 7 becomes the same as in FIG. 3. As is apparent from FIG. 7, T1 and T2 are formed in regions outside the region where Pd is formed.

The basic operation of the semiconductor device 100a is the same as that of the first embodiment. Adjust the number and order of control MOSFETs T1 to Tn to turn on when turning off Pd. As a result, the slew rate at the time of turn-off of Pd can be adjusted.

As described above, in the semiconductor device 100a according to the second embodiment, the same effect as that of the first embodiment can be obtained. Further, the variable width of the slew rate at the time of turning-off of Pd can be enlarged as compared with the first embodiment.

### Third Embodiment

FIG. 8 is a block diagram showing a configuration of a semiconductor device 100b according to third embodiment. The difference from the first embodiment is that an N-channel MOSFET Ts for blocking Pd and an MCU (Micro Controller Unit) 102 for controlling T1 and Ts are added.

Basic operation of the semiconductor device 100b is the same as in the first embodiment, Ts is controlled by the MCU. When it is necessary to shut off Pd in an emergency or the like, the MCU can forcibly shut off Pd by turning on Ts.

As described above, in the semiconductor device 100b according to the third embodiment, in addition to the effect of the first embodiment, Pd can be forcibly shut off.

It should be noted that the present invention is not limited to the above-mentioned embodiments, and various modifications can be made without departing from the gist thereof.

What is claimed is:

1. A semiconductor device comprising:
a first power semiconductor device;
a first Nch MOSFET whose drain is coupled to a gate of the first power semiconducting device;
a first gate resistor coupled to a source of the first Nch MOSFET; and
a first diode coupled between the source and the drain of the first Nch MOSFET.

2. The semiconductor device according to claim 1,
wherein a first control signal is inputted to the gate of the first power semiconductor device via the first gate resistor and the first Nch MOSFET,
wherein a second control signal is inputted to the first Nch MOSFET, and
wherein the first and second control signals are generated such that the first Nch MOSFET is turned on (off) when the first power semiconductor device is turned off (on).

3. The semiconductor device according to claim wherein the first Nch MOSFET is composed of a plurality of N-ch MOSFETs coupled in parallel.

4. The semiconductor device according to claim 1, further comprising:
a shut-off MOSFET for shutting off the first power semiconductive device,
wherein the shut-off MOSFET is coupled to the gate of the first power semiconductor device.

5. The semiconductor device according to claim further comprising:
a second power semiconductor device coupled in series with the first power semiconductor device.

6. The semiconductor device according to claim 5, further comprising:
a second Nch MOSFET whose drain is coupled to a gate of the second power semiconducting device;
a second gate resistor coupled to a source of the second Nch MOSFET; and
a second diode coupled between the source and drain of the second Nch MOSFET.

7. The semiconductor device according to claim 6,
wherein a third control signal is inputted to the gate of the second power semiconductor device via the second gate resistor and the second Nch MOSFET,
wherein a fourth control signal is inputted to the second Nch MOSFET, and
wherein the third and fourth control signals are generated such that the second Nch MOSFET is turned on (off) when the second power semiconductor device is turned off (on).
